(19) United States
(12) Patent Application Publication
(10) Pub. No.: US 2008/0197384 A1
(43) Pub. Date: Aug. 21, 2008

(54) Field Effect Transistor Arrangement

(76) Inventors: Jessica Hartwich, Dresden (DE); Lars Dreeskornfeld, Dresden (DE); Gernot Steinlesberger, Otterfing Bergham (DE)

Correspondence Address: SLATER & MATSIL, L.L.P., 17950 PRESTON ROAD, SUITE 1000, DALLAS, TX, 75252, US

(21) Appl. No.: 12/035,195

(22) Filed: Feb. 21, 2008

(30) Foreign Application Priority Data
Feb. 21, 2007 (DE) 10 2007 008 562.3

(51) Int. Cl. H01L 29/423; H01L 21/336

(52) U.S. Cl. 257/288; 438/197; 257/E29.13

(57) ABSTRACT

A field effect transistor arrangement includes an electrically insulating layer, a source region, a drain region and a channel region arranged between source region and drain region, wherein the source region, the drain region and the channel region are in each case arranged on or above the electrically insulating layer, and also a gate region having an electrically insulating gate layer and an electrically conductive gate layer, which adjoins the channel region or is arranged at a distance from the latter and which extends at least partly along the channel region, wherein the source region and the drain region are in each case produced from electrically conductive carbon, and wherein the channel region is produced from strained silicon.

This application claims priority to German Patent Application DE 10 2007 008 562.3, which was filed Feb. 21, 2007 and is incorporated herein by reference.

### TECHNICAL FIELD

Embodiments of the invention relate generally to semiconductor components and specifically to a field effect transistor arrangement.

### BACKGROUND

In order to meet the requirements of the ITRS (“International Technology Roadmap for Semiconductors”) various novel structures and new materials have been proposed for field effect transistor arrangements.

The various structures include, for example, so-called Fully Depleted Silicon-On-Insulator (FD SOI) devices and so-called Multigate Field Effect Transistors (MuGFETs) having a double-gate structure or trigate structure.

Field effect transistor arrangements having the structures mentioned above may have the following properties, inter alia. Firstly, it may be difficult to make contact with the source region and the drain region with a low connection resistance, that is to say that making contact with the source region and the drain region may be generally possible only with an increased connection resistance. Moreover, the threshold voltage is usually set by means of the doping of the channel. A setting of the threshold voltage by way of the gate material may be generally only possible in the case of polysilicon gates. Furthermore, the mobility of the electrons and the holes in the (ultrathin) channel region may be generally adversely affected to a relatively great extent.

The relatively recent materials which are used for the channel region or the active channel layer include, for example, stretched or strained silicon.

### SUMMARY OF THE INVENTION

A field effect transistor arrangement in accordance with an embodiment includes an electrically insulating layer, a source region, a drain region and a channel region arranged between source region and drain region, wherein the source region, the drain region and the channel region are in each case arranged on or above the electrically insulating layer, and also a gate region having an electrically insulating gate layer and an electrically conductive gate layer, which adjoins the channel region or is arranged at a distance from the latter and which extends at least partly along the channel region, wherein the electrically conductive gate layer of the gate region is produced from electrically conductive carbon and/or the source region and the drain region are in each case produced from electrically conductive carbon, and wherein the channel region is produced from strained silicon.

### BRIEF DESCRIPTION OF THE DRAWINGS

In the drawings, identical elements are provided with identical reference symbols. The illustrations shown in the figures are depicted schematically and not true to scale. Various embodiments of the invention are described below with reference to the following drawings, in which:

FIG. 1 shows a field effect transistor arrangement in accordance with a first embodiment;

FIG. 2 shows a field effect transistor arrangement in accordance with a second embodiment;

FIG. 3 shows a cross-sectional view of a field effect transistor arrangement in accordance with a third embodiment; and

FIG. 4 shows a cross-sectional view of a field effect transistor arrangement in accordance with a fourth embodiment.

### DETAILED DESCRIPTION OF ILLUSTRATIVE EMBODIMENTS

In accordance with the first embodiment shown in FIG. 1 a field effect transistor arrangement 100 has a fin structure. Field effect transistor arrangements of this type are usually referred to as Multigate Field Effect Transistors (MuGFETs) or Fin Field Effect Transistors (FinFETs).

The field effect transistor arrangement 100 shown in FIG. 1 has a fin 102 (also referred to as a bar). There are formed in the fin 102 a source region 108, which is arranged at a first end of the fin 102, a drain region 110, which is arranged at a second end of the fin 102, and a channel region 112 arranged between the source region 108 and the drain region 110.

The field effect transistor arrangement 100 shown in FIG. 1 furthermore has a gate region having a first electrically conductive gate layer 104 and a second electrically conductive gate layer 106, which are arranged laterally alongside the fin 102 at a distance from the latter and which at least partly surround the side areas of the channel region 112. Moreover, the gate region has a first thin electrically insulating gate layer (not shown) and a second thin electrically insulating gate layer (not shown). The first electrically conductive gate layer 104 and the second electrically conductive gate layer 106 are electrically insulated from the fin 102 and from the channel region 112 by means of the first electrically insulating gate layer and the second electrically insulating gate layer, respectively. For this purpose, the two side walls of the fin 102, that is to say the areas/outer sides of the fin 102 which face the first electrically conductive gate layer 104 and the second electrically conductive gate layer 106, are covered at least along a partial region of the channel region 112 with the first electrically insulating gate layer (not shown) and the second electrically insulating gate layer (not shown), respectively, and the first electrically conductive gate layer 104 and the second electrically conductive gate layer 106 are deposited/arranged on the first electrically insulating gate layer and the second electrically insulating gate layer, respectively.

The fin 102, having the source region 108, the drain region 110 and the channel region 112, and the gate region, having the first electrically conductive gate layer 104, the second electrically conductive gate layer 106, the first electrically insulating gate layer and the second electrically insulating gate layer, are arranged above a substrate layer 130 and electrically insulated from the substrate layer 130 by means of an electrically insulating layer 120.

The field effect transistor arrangement 100 shown in FIG. 1 has a double-gate FinFET structure, that is to say that the gate region 104 includes two electrically conductive gate layers. In accordance with another embodiment it is possible to provide a further electrically conductive gate layer above the fin 102 or above the channel region 112 and/or a further electrically conductive gate layer below the fin 102 or below the channel region 112, that is to say above the area/outer side of the fin 102 that is remote from the substrate layer 130 and/or below the area/outer side of the fin 102 that faces the substrate layer 130, wherein each further electrically conductive gate layer may be electrically insulated from the channel region 112 by the provision of a further electrically insulating gate layer between the further electrically conductive gate layer and the fin 102. In this way, a driving of the fin 102 from three (trigate structure) or four sides may be made possible.

In accordance with one embodiment, the fin 102, and thus the source region 108, the drain region 110 and the channel region 112, may have, for example, a height of about 20 nm to about 100 nm and a width of about 10 nm to about 100 nm. In accordance with another embodiment, the width of the fin 102 may be limited to the range of between about 20 nm and about 50 nm. In accordance with a further embodiment, the width of the fin 102 may be approximately 40 nm. In accordance with another embodiment, the fin may have a height of approximately 50 nm. The total length of the fin 102 may be, for example, about 10 nm to about 10 μm.

In accordance with the first embodiment, the source region 108 and the drain region 110 are in each case produced from electrically conductive carbon and may be formed with the aid of the deposition method described in the introduction.

The channel region 112 is produced from strained silicon, wherein the strained silicon is arranged directly on the insulated substrate layer 130, that is to say directly on the electrically insulating layer 120.

In accordance with one embodiment, the height of the first electrically conductive gate layer 104 and of the second electrically conductive gate layer 106 may lie within the range of between about 20 nm and about 100 nm. In accordance with another embodiment, the first electrically conductive gate layer 104 and the second electrically conductive gate layer 106 may have a height of approximately 50 nm. The thickness of the electrically insulating gate layers may be for example in each case about 2 nm to about 5 nm.

In accordance with the first embodiment, the first electrically conductive gate layer 104 and the second electrically conductive gate layer 106 are in each case produced from electrically conductive carbon and may be formed with the aid of the deposition method described in the introduction. By way of example, the carbon deposition may be effected at a temperature which is higher than the temperatures usually employed during the deposition of metal gates and which lies below the annealing temperature after an implantation. In accordance with an alternative embodiment it is provided for the first electrically conductive gate layer 104 the second electrically conductive gate layer 106 to be formed as a common (continuous) layer. The strained silicon in the channel region 112 or the strain state of the silicon may be maintained even at higher temperatures.

The first electrically insulating gate layer and the second electrically insulating gate layer may be, for example, in each case an oxide layer, for example, composed of silicon oxide, or a nitride layer.

The substrate layer 130 may be, for example, a silicon substrate layer and may have a thickness of about 50 nm to about 200 nm. By way of example, the thickness of the substrate layer 130 may be approximately 100 nm.

The electrically insulating layer 120 may be, for example, an oxide layer, for example, composed of silicon dioxide, and may have a thickness of about 50 nm to about 200 nm. By way of example, the thickness of the electrically insulating layer 120 may be approximately 100 nm.

Since the channel region 112 is produced from strained silicon, the charge carrier mobility in the channel region 112 may be significantly increased in comparison with conventional field effect transistor arrangements. Moreover, germanium diffusion into the layer composed of the strained silicon may not occur since the layer composed of the strained silicon is arranged directly on the electrically insulating layer 120.

The electrically conductive carbon used for the production of the source region 108 and of the drain region 110 and also for the production of the first electrically conductive gate layer 104 and of the second electrically conductive gate layer 106 may have a significantly higher/better chemical and thermal stability in comparison with those materials/metals which are usually used for the production of the regions mentioned. Thus, electrically conductive carbon, e.g., may not react with aluminum, tungsten and/or copper, and may withstand, for example, even temperatures of more than about 1000° C. during crystallization steps which may be carried out when forming so-called high-k dielectrics, that is to say electrically insulating materials having a high relative permittivity. Furthermore, layers composed of electrically conductive carbon, and thus the corresponding regions which are produced from the electrically conductive carbon, may be deposited/formed in simple steps on account of the very good properties of carbon with regard to the processability, and the deposited layers having electrically conductive carbon may be patterned in a simple manner. Consequently, the field effect transistor arrangement 100 may be produced in a simple and efficient manner.

Through the use of electrically conductive carbon, the source region 108 and the drain region 110 may furthermore be formed with a resistivity comparable with that of metals. What may be achieved, in particular, is that in the case of small feature sizes, e.g., feature sizes of less than about 100 nm, electron scattering processes in the source region 108 and in the drain region 110 are reduced, such that there may be no rise in resistivity as can be observed for metals, for which the resistivity afforded for macroscopic systems cannot be achieved at feature sizes of less than about 100 nm. Furthermore, the effect of a very low connection resistance for making contact with the two regions may result from the use of electrically conductive carbon for the source region 108 and the drain region 110.

Through the use of electrically conductive carbon for the production of the first electrically conductive gate layer 104 and of the second electrically conductive gate layer 106, it may be possible to set the threshold voltage V_{T} by way of the gate material, such that a channel implantation/channel doping may be obviated. Moreover, a gate implantation or gate doping as when polysilicon is used may be avoided. Furthermore, when electrically conductive carbon is used, there may be no diffusion of atoms into the channel region as when metal gates are used.

In addition to the abovementioned effects resulting in each case from the use of electrically conductive carbon and from the use of strained silicon, it may be possible, through the use of electrically conductive carbon for the electrically conductive gate layers 104, 106 and also for the source region 108 and the drain region 110 in combination with the use of strained silicon for the channel region 112, to stabilize the channel region 112 and the strained silicon in the channel region 112, that is to say that the strained silicon may be better preserved.

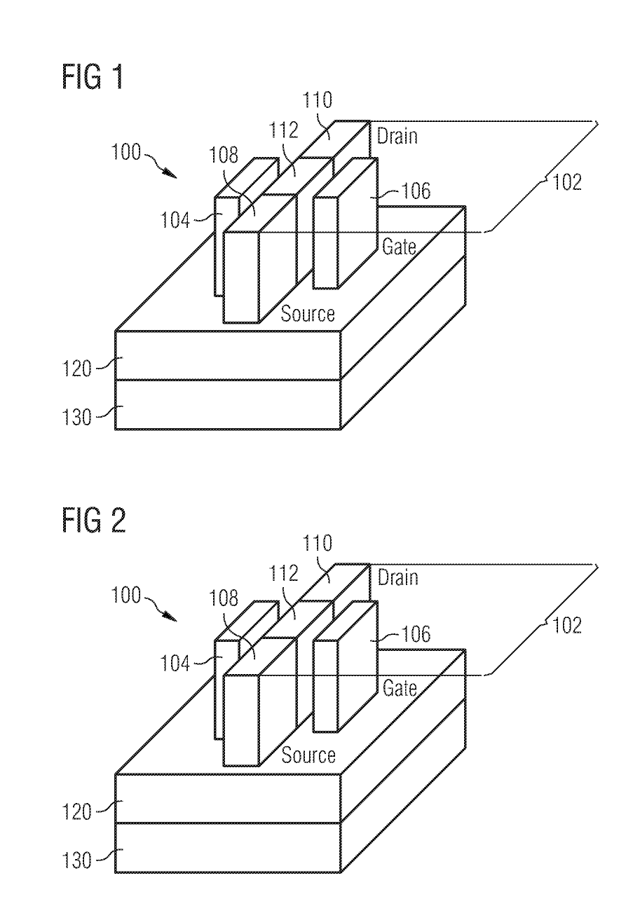

The field effect transistor arrangement 100 in accordance with the second embodiment as shown in FIG. 2 has the same structure as the field effect transistor arrangement 100 in accordance with the first embodiment as shown in FIG. 1, wherein in the second embodiment only the first electrically conductive gate layer 104 and the second electrically conductive gate layer 106 are produced from electrically conductive carbon, and wherein the source region 108 and the drain region 110 are produced from a different material, such as silicon, for example. The dimensions of the individual regions and the materials used for the channel region 112, the two electrically insulating gate layers, the electrically insulating layer 120 and the substrate layer 130 are unchanged with respect to the first embodiment.

In accordance with another embodiment it is possible to produce only the source region 108 and/or the drain region 110 from electrically conductive carbon and to produce the electrically conductive gate layers 104, 106 of the gate region from a different material, such as polysilicon for example.

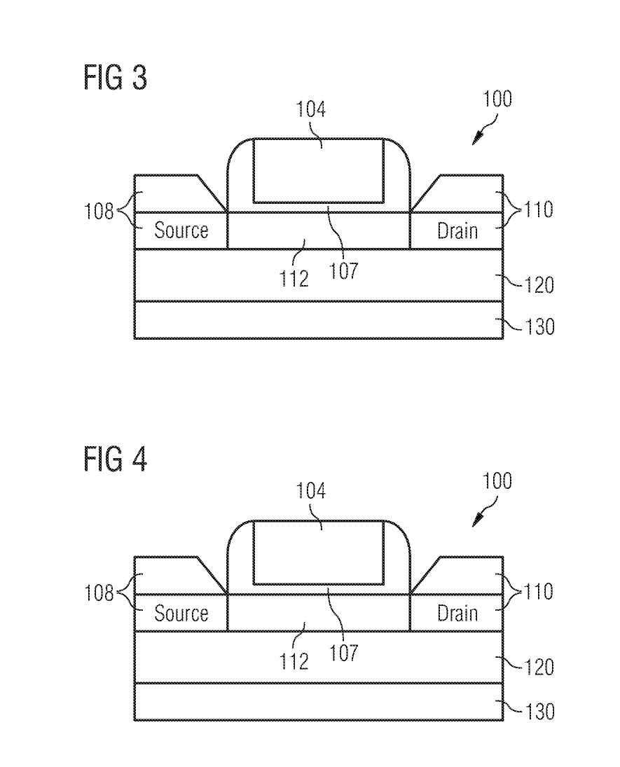

In accordance with the third embodiment shown in FIG. 3, the field effect transistor arrangement 100 has a planar structure.

The source region 108, the drain region 110 and the channel region 112 are formed on the electrically insulating gate layer 120, which is arranged on the substrate layer 130, wherein the source region 108 and the drain region 110 are elevated (in other words, raised) with respect to the channel region 112. By way of example, the source region 108 and the drain region 110 may be elevated by means of selective epitaxy. The source region 108, the drain region 110 and the channel region 112 are formed in planar fashion and in each case have a horizontal structure, that is to say that their extent in a horizontal direction is significantly larger than their extent in a vertical direction. The gate region having an electrically insulating gate layer 107 and an electrically conductive gate layer 104 is formed on the channel region 112. The electrically insulating gate layer 107 surrounds the electrically conductive gate layer 104 at the underside and at the side areas thereof, such that the electrically conductive gate layer 104 is electrically insulated from the channel region 112 and also from the source region 108 and the drain region 110.

In accordance with this embodiment, the channel region 112 may be formed as a very thin channel layer having a thickness of less than or equal to about 10 nm, for example. The thickness of the channel region 112 and the length of the gate region may be, for example, in a ratio of 1:4 relative to one another, whereby a small off-current may be achieved. Analogously to the first embodiment and the second embodiment, the channel region 112 is produced from strained silicon, and the strained silicon or the channel region 112 composed of the strained silicon is arranged directly on the electrically insulating layer 120.

The source region 108 and the drain region 110 may, for example, in each case be produced from silicon or alternatively be formed from metal.

The electrically conductive gate layer 104 is produced from electrically conductive carbon and may be formed with the aid of the deposition method described in the introduction. The electrically insulating gate layer 107 is a dielectric layer or a high-k dielectric layer and may be, for example, an oxide layer, for example, a silicon oxide layer, or a nitride layer.

Analogously to the first embodiment and the second embodiment, the substrate layer 130 may be, for example, a silicon substrate layer, and the electrically insulating layer 120 may be, for example, an oxide layer, for example, composed of silicon dioxide.

The field effect transistor arrangement 100 in accordance with the fourth embodiment as shown in FIG. 4 has the same structure as the field effect transistor arrangement 100 in accordance with the third embodiment. However, the source region 108 and the drain region 110 of the field effect transistor arrangement 100 in accordance with the fourth embodiment are in each case produced from electrically conductive carbon, that is to say that both the electrically conductive gate layer 104 and the source region 108 and the drain region 110 are produced from electrically conductive carbon in accordance with the fourth embodiment.

In accordance with another embodiment it is possible to produce only the source region 108 and/or the drain region 110 from electrically conductive carbon and to produce the electrically insulating gate layer 104 from a different material such as polysilicon, for example.

As for the first embodiment, it may also hold true for the second, the third and the fourth embodiment that the charge carrier mobility in the channel region 112 produced from strained silicon may be significantly increased in comparison with conventional field effect transistor arrangements, in which case the strained silicon in the channel region 112 or the strain state of the silicon may be stabilized or better preserved through the use of electrically conductive carbon for the electrically conductive gate layer and/or for the source region 108 and/or the drain region 110 in combination with the use of strained silicon for the channel region 112.

By virtue of the fact that the active channel layer or the channel region is produced using strained silicon, the mobility of the electrons and the holes in the channel region may be significantly increased in comparison with conventional field effect transistor arrangements. By way of example, for a tensile stress increased by approximately 1.3%, the mobility of the electrons may be increased by more than 100% and the mobility of the holes may be increased by approximately 40%. In this case, the strained silicon may be applied on an SiGe layer or directly on the electrically insulating layer, that is to say directly on the insulated wafer.

The use of electrically conductive or metallic carbon for the production of the electrically conductive gate layer may result in the following effects, for example. Since carbon is a mid-gap material, it may be possible to set the threshold voltage V_{T} for NMOS and PMOS solely by way of the gate material or the electrically conductive carbon. A channel implantation or a channel doping may thus be avoided. Moreover, electrically conductive carbon may be readily compatible with the rest of the process materials and process parameters. By way of example, electrically conductive carbon may exhibit good deposition properties on the electrically insulating gate layer (e.g., gate oxide), that is to say that it may readily be deposited on/above the electrically insulating gate layer. Furthermore, it may have a good temperature resistance, and a deposited carbon layer may be patterned/etched back in a simple manner by means of dry etching. Furthermore, electrically conductive carbon may be very stable, that is to say that it may have a higher chemical and thermal stability than the metals that are usually used, and there may be no diffusion of atoms of the gate region into the channel region as when other possible materials are used for the electrically conductive gate layer (e.g., metal gates). Moreover, a gate implantation or gate doping as in the case of polysilicon may be avoided.

If electrically conductive carbon is used for the production of the source region and of the drain region, the connection resistance for making contact with the source region and the drain region may be considerably reduced. Moreover, it may be possible to exploit the abovementioned effects of the electrically conductive carbon, such as, for example, a good compatibility with the rest of the process materials and process parameters, good deposition properties, a good temperature resistance, a good patternability and a good stability. Furthermore, through the use of electrically conductive carbon, the source region and the drain region may be formed in such a way that they have a resistivity comparable with that of metals. What may be achieved, in particular, by using electrically conductive carbon for the production of the source region and of the drain region is that in the case of small feature sizes, e.g., feature sizes of less than about 100 nm, electron scattering processes may be reduced, such that there may be no rise in resistivity as can be observed for metals, for which the resistivity afforded for macroscopic systems cannot be achieved at feature sizes of less than 100 nm.

The abovementioned effects achieved by the use of electrically conductive or metallic carbon for the production of the electrically conductive gate layer and/or the source region and of the drain region may also have the result that the channel region produced from the strained silicon may be particularly stable and better preserved when electrically conductive carbon is used for the gate region and/or for the source region and the drain region, that is to say that the channel region having the strained silicon may be more likely to be preserved in the combination with carbon as material for the electrically conductive gate layer and/or as source material and drain material than in the combination with other gate, source and drain materials. In some embodiments, therefore, the use of strained silicon for the production of the channel region may be combined with the use of electrically conductive carbon as material for the electrically conductive gate layer and/or as source material and drain material.

In accordance with one embodiment, the electrically conductive gate layer of the gate region and/or the source region and the drain region may in each case be composed exclusively of electrically conductive carbon.

In accordance with another embodiment, the channel region may, for example, be composed exclusively of strained silicon.

If the channel region is composed exclusively of strained silicon, a germanium diffusion into the strained silicon may be avoided/precluded by virtue of the absence of SiGe, and there may be no need to develop any new processing steps for SiGe. By way of example, the channel region may be arranged directly on the electrically insulating layer or on an insulated wafer and be composed exclusively of strained silicon, such that the field effect transistor arrangement has an SSDOI (Strained Silicon directly on Insulator) structure.

In accordance with one embodiment, the source region, the drain region and the channel region may be formed as a fin and in each case have a vertical structure. In this case, the gate region may be arranged, for example, on or above the channel region and/or adjoin at least one side area of the channel region or be arranged alongside at least one side area of the channel region at a distance from the latter.

In this way, the channel region having strained silicon may be driven even better by means of the gate region having the electrically conductive gate layer produced from electrically conductive carbon.

In accordance with another embodiment, the source region, the drain region and the channel region may in each case have a horizontal structure and be formed in planar fashion in such a way that the source region, the drain region and the channel region essentially lie in the same plane or the source region and the drain region are in each case elevated with respect to the channel region, wherein the gate region is arranged on or above the channel region.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes that come within the meaning and range of equivalency of the claims are intended to be embraced.

What is claimed is:

1. A field effect transistor comprising:
an electrically insulating layer;
a source region, a drain region, and a channel region arranged between the source region and the drain region, the source region, the drain region and the channel region each arranged over the electrically insulating layer, wherein the source region and the drain region each comprise electrically conductive carbon and wherein the channel region comprises strained silicon; and
a gate region having an electrically insulating gate layer and an electrically conductive gate layer, the gate region adjacent the channel region.

2. The field effect transistor as claimed in claim 1, wherein the electrically conductive gate layer of the gate region comprises electrically conductive carbon.

3. The field effect transistor as claimed in claim 1, wherein the source region and the drain region are each composed exclusively of electrically conductive carbon.

4. The field effect transistor as claimed in claim 2, wherein the electrically conductive gate layer of the gate region is composed exclusively of electrically conductive carbon.

5. The field effect transistor as claimed in claim 4, wherein the source region and the drain region are each composed exclusively of electrically conductive carbon.

6. The field effect transistor as claimed in claim 1, wherein the channel region is composed exclusively of strained silicon.

7. The field effect transistor as claimed in claim 2, wherein the channel region is composed exclusively of strained silicon.

8. The field effect transistor as claimed in claim 1, wherein the source region, the drain region and the channel region are formed as a fin and each have a vertical structure.

9. The field effect transistor as claimed in claim 8, wherein the gate region is arranged on or above the channel region or adjoins at least one side area of the channel region or is arranged alongside at least one side area of the channel region at a distance from the latter.

10. The field effect transistor as claimed in claim 8, wherein the gate region is arranged on or above the channel region and adjoins at least one side area of the channel region or is arranged alongside at least one side area of the channel region at a distance from the latter.

11. The field effect transistor as claimed in claim 2, wherein the source region, the drain region and the channel region are formed as a fin and in each case have a vertical structure.

12. The field effect transistor as claimed in claim 11, wherein the gate region is arranged on or above the channel region or adjoins at least one side area of the channel region or is arranged alongside at least one side area of the channel region at a distance from the latter.

13. The field effect transistor as claimed in claim 11, wherein the gate region is arranged on or above the channel region and adjoins at least one side area of the channel region or is arranged alongside at least one side area of the channel region at a distance from the latter.

14. The field effect transistor as claimed in claim 1, wherein the source region, the drain region and the channel region in each case have a horizontal structure and are formed in planar fashion, in such a way that the source region, the drain region and the channel region essentially lie in the same plane or the source region and the drain region are in each case elevated with respect to the channel region, and wherein the gate region is arranged on or above the channel region.

15. The field effect transistor as claimed in claim 1, wherein the gate region adjoins the channel region.

16. The field effect transistor as claimed in claim 1, wherein the gate region is arranged at a distance from the channel region and extends at least partly along the channel region.

17. A method for producing a field effect transistor, the method comprising:
forming an electrically insulating layer over a substrate;
forming a source region, a drain region and a channel region arranged between the source region and the drain region, the source region, the drain region and the channel region being formed over the electrically insulating layer; and
forming a gate region adjacent the channel region, the gate region having an electrically insulating gate layer and an electrically conductive gate layer,
wherein the source region and the drain region are in each case formed from electrically conductive carbon and wherein the channel region is formed from strained silicon.
